(19) United States
(12) Patent Application Publication
(10) Pub. No.: US 2024/0280609 A1
(43) Pub. Date: Aug. 22, 2024

(54) ELECTRICALLY CONDUCTIVE CONTACT PIN

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Sung Hyun BYUN, Gyeonggi-do (KR)

(73) Assignee: POINT ENGINEERING CO., LTD., Chungcheongnam-do (KR)

(21) Appl. No.: 18/567,345

(22) PCT Filed: Jun. 3, 2022
(86) PCT No.: PCT/KR2022/007942

§ 371 Date: Dec. 5, 2023

(30) Foreign Application Priority Data
Jun. 7, 2021 (KR) 10-2021-0073224

(51) Int. Cl. G01R 1/067

(52) U.S. Cl. CPC G01R 1/06761

(57) ABSTRACT

The present invention provides an electrically conductive contact pin formed by laminating a plurality of metal layers, wherein the electrically conductive contact pin has improved physical or electrical properties.

### TECHNICAL FIELD

The present disclosure relates to an electrically conductive contact pin.

### BACKGROUND ART

Electrically conductive contact pins are contact pins that can be used in probe cards or test sockets that contact and inspect an object. Hereinafter, contact pins of a probe card will be described as an example.

A test for electrical characteristics of a semiconductor device is performed by approaching a wafer to a probe card having a plurality of electrically conductive contact pins and then bringing the respective electrically conductive contact pins into contact with corresponding electrode pads on the wafer. After the electrically conductive contact pins reach positions where they are brought into contact with the electrode pads, a process of further approaching the wafer to the probe card is performed. This process is called overdrive. Overdrive is a process that elastically deforms the electrically conductive contact pins. By overdrive, all electrically conductive contact pins can be reliably brought into contact with the electrode pads even when there is a height difference between the electrode pads or the electrically conductive contact pins. During overdrive, each electrically conductive contact pin is elastically deformed, and performs scrubbing while a tip thereof moves on an electrode pad. By such scrubbing, an oxide film on a surface of the electrode pad can be removed and contact resistance can be reduced thereby.

Meanwhile, electrically conductive contact pins may be manufactured using an MEMS process. A process of manufacturing an electrically conductive contact pin using the MEMS process involves first applying a photoresist to a surface of a conductive substrate and then patterning the photoresist. After that, a metal material is deposited within openings by electroplating using the photoresist as a mold, and the photoresist and the conductive substrate are removed to obtain electrically conductive contact pins.

However, conventional electrically conductive contact pins have limitations in improving their physical or electrical properties.

### DOCUMENTS OF RELATED ART

### Patent Documents

(Patent Document 1) Korean Patent No. 10-0449308

### DISCLOSURE

### Technical Problem

Accordingly, the present disclosure has been made keeping in mind the above problems occurring in the related art, and an objective of the present disclosure is to provide an electrically conductive contact pin formed by stacking a plurality of metal layers, in which the electrically conductive contact pin has improved physical or electrical properties.

### Technical Solution

In order to accomplish the above objective, the present disclosure provides an electrically conductive contact pin, including: a body portion formed by stacking a plurality of metal layers; and a tip portion located at an end of the body portion, and in contact with the plurality of metal layers constituting the body portion at joint interfaces between the tip portion and the body portion.

In addition, the body portion may include: a first metal; and a second metal. Here, the first metal may form an outer surface of the body portion, and the second metal may be located inside the body portion.

In addition, the body portion may include: a first metal; and a second metal. Here, the first metal 210 may be made of a metal selected from the group consisting of rhodium (Rd), platinum (Pt), iridium (Ir), palladium (Pd), and an alloy of these metals; the group consisting of a palladium-cobalt (PdCo) alloy and a palladium-nickel (PdNi) alloy; or the group consisting of a nickel-phosphor (NiPh) alloy, a nickel-manganese (NiMn), a nickel-cobalt (NiCo), and a nickel-tungsten (NiW) alloy, and the second metal 230 may be made of a metal selected from the group consisting of copper (Cu), silver (Ag), gold (Au), and an alloy of these metals.

In addition, the tip portion may have the same height as the body portion.

In addition, the tip portion may be embedded in a recess portion formed in the body portion so that three surfaces of the tip portion are in contact with the body portion.

In addition, the tip portion may be embedded in the body portion so that three surfaces thereof are exposed, and the tip portion may not protrude from the end of the body portion.

In addition, the tip portion may be at least partially embedded in the body portion so that at least three surfaces thereof are exposed.

In addition, the tip portion may include: a first portion in contact with the plurality of metal layers constituting the body portion at the joint interfaces between the tip portion and the body portion; and a second portion formed at the first portion, having a lower height than the first portion, and coming into contact with an object.

In addition, the tip portion may include: a first portion in contact with the plurality of metal layers constituting the body portion at the joint interfaces between the tip portion and the body portion; and a second portion formed at the first portion, having the same height as, but a narrower width than the first portion, and coming into contact with an object.

In addition, the tip portion may include: a first portion in contact with the plurality of metal layers constituting the body portion at the joint interfaces between the tip portion and the body portion and at least partially embedded in the body portion; and a second portion formed at the first portion and coming into contact with an object.

In addition, at each joint interface, the body portion may be provided with a first engaging portion, and the tip portion may be provided with a second engaging portion coupled to the first engaging portion to form a coupling reinforcement structure.

In addition, the first engaging portion may be provided at the body portion along a height direction of the joint interface, and the second engaging portion may be provided at the tip portion along the height direction of the joint interface.

In addition, the first engaging portion may be provided at the body portion along a perimeter direction of the joint interface, and the second engaging portion may be provided at the tip portion along the perimeter direction of the joint interface.

### Advantageous Effects

The present disclosure provides an electrically conductive contact pin formed by stacking a plurality of metal layers, in which the electrically conductive contact pin has improved physical or electrical properties.

### DESCRIPTION OF DRAWINGS

FIG. 1a is a front perspective view illustrating an electrically conductive contact pin according to a first embodiment of the present disclosure.

FIG. 1b is an exploded front perspective view illustrating a tip portion at a first end of the electrically conductive contact pin according to the first embodiment of the present disclosure.

FIG. 2a is a rear perspective view illustrating the electrically conductive contact pin according to the first embodiment of the present disclosure.

FIG. 2b is an exploded rear perspective view illustrating a tip portion at a second end of the electrically conductive contact pin according to the first embodiment of the present disclosure.

FIG. 3a is a plan view illustrating the electrically conductive contact pin according to the first embodiment of the present disclosure.

FIG. 3b is a sectional view taken along line A-A of FIG. 3a.

FIG. 4a is a perspective view illustrating an end of an electrically conductive contact pin according to a second embodiment of the present disclosure.

FIG. 4b is an exploded perspective view illustrating a tip portion illustrated in FIG. 4a.

FIG. 5a is a perspective view illustrating an end of an electrically conductive contact pin according to a third embodiment of the present disclosure.

FIG. 5b is an exploded perspective view illustrating a tip portion illustrated in FIG. 5a.

FIG. 6a is a perspective view illustrating an end of an electrically conductive contact pin according to a fourth embodiment of the present disclosure.

FIG. 6b is an exploded perspective view illustrating a tip portion illustrated in FIG. 6a.

FIG. 7a is a perspective view illustrating an end of an electrically conductive contact pin according to a fifth embodiment of the present disclosure.

FIG. 7b is an exploded perspective view illustrating a tip portion illustrated in FIG. 7a.

FIG. 8a is a perspective view illustrating an end of an electrically conductive contact pin according to a sixth embodiment of the present disclosure.

FIG. 8b is an exploded perspective view illustrating a tip portion illustrated in FIG. 8a.

FIG. 9a is a perspective view illustrating an end of an electrically conductive contact pin according to a seventh embodiment of the present disclosure.

FIG. 9b is an exploded perspective view illustrating a tip portion illustrated in FIG. 9a.

FIG. 10a is a perspective view illustrating an end of an electrically conductive contact pin according to an eighth embodiment of the present disclosure.

FIG. 10b is an exploded perspective view illustrating a tip portion illustrated in FIG. 10a.

FIG. 11a is a perspective view illustrating an end of an electrically conductive contact pin according to a ninth embodiment of the present disclosure.

FIG. 11b is an exploded perspective view illustrating a tip portion illustrated in FIG. 11a.

FIG. 12a is a perspective view illustrating an end of an electrically conductive contact pin according to a tenth embodiment of the present disclosure.

FIG. 12b is an exploded perspective view illustrating a tip portion illustrated in FIG. 12a.

FIG. 13a is a perspective view illustrating an end of an electrically conductive contact pin according to an eleventh embodiment of the present disclosure.

FIG. 13b is an exploded perspective view illustrating a tip portion illustrated in FIG. 13a.

FIG. 14a is a perspective view illustrating an end of an electrically conductive contact pin according to a twelfth embodiment of the present disclosure.

FIG. 14b is an exploded perspective view illustrating a tip portion illustrated in FIG. 14a.

FIG. 14c is a sectional view taken along line A-A′ of FIG. 14a.

### MODE FOR INVENTION

Contents of the description below merely exemplify the principle of the present disclosure. Therefore, those of ordinary skill in the art may implement the theory of the present disclosure and invent various apparatuses which are included within the concept and the scope of the present disclosure even though it is not clearly explained or illustrated in the description. Furthermore, in principle, all the conditional terms and embodiments listed in this description are clearly intended for the purpose of understanding the concept of the present disclosure, and one should understand that the present disclosure is not limited to the exemplary embodiments and the conditions.

The above described objectives, features, and advantages will be more apparent through the following detailed description related to the accompanying drawings, and thus those of ordinary skill in the art may easily implement the technical spirit of the present disclosure.

The embodiments of the present disclosure will be described with reference to cross-sectional views and/or perspective views which schematically illustrate ideal embodiments of the present disclosure. For explicit and convenient description of the technical content, thicknesses of films and regions in the figures may be exaggerated. Therefore, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. The technical terms used herein are for the purpose of describing particular embodiments only and should not be construed as limiting the present disclosure. As used herein, the singular forms are intended to include the plural forms as well, unless the context clearly indicates otherwise. It will be further understood that the terms “comprise”, “include”, “have”, etc. when used herein, specify the presence of stated features, integers, steps, operations, elements, components, and/or combinations thereof but do not preclude the presence or addition of one or more other features, integers, steps, operations, elements, components, and/or combinations thereof.

Hereinafter, exemplary embodiments of the present disclosure will be described in detail with reference to the accompanying drawings. Wherever possible, the same reference numerals will be used throughout different embodiments and the description to refer to the same or like elements or parts. In addition, the configuration and operation already described in other embodiments will be omitted for convenience.

Hereinafter, first to twelfth embodiments will be separately described, but embodiments in which the elements of each embodiment are combined are also included in exemplary embodiments of the present disclosure.

### First Embodiment

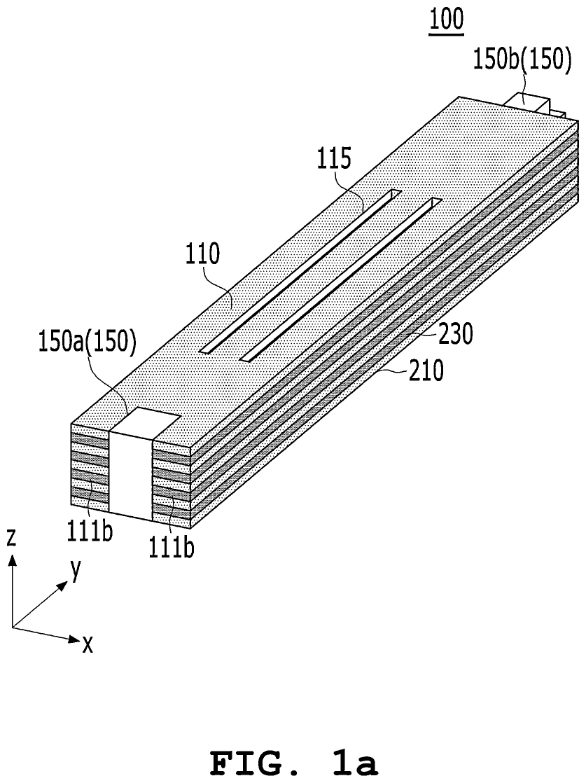

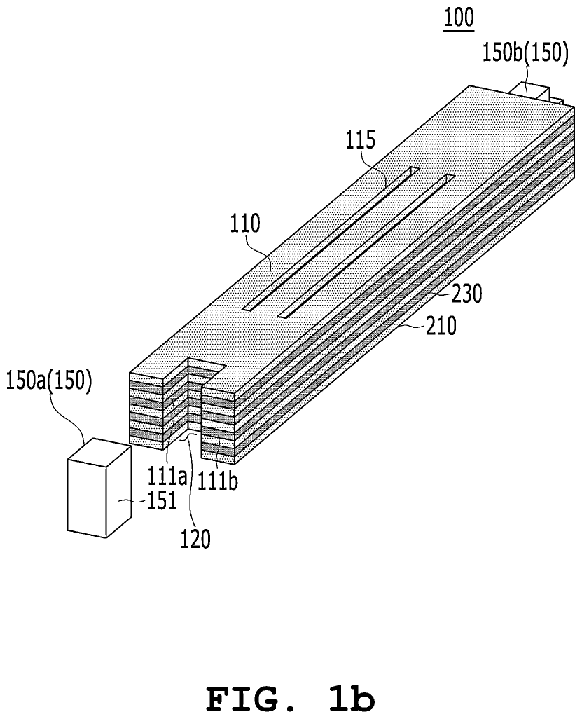

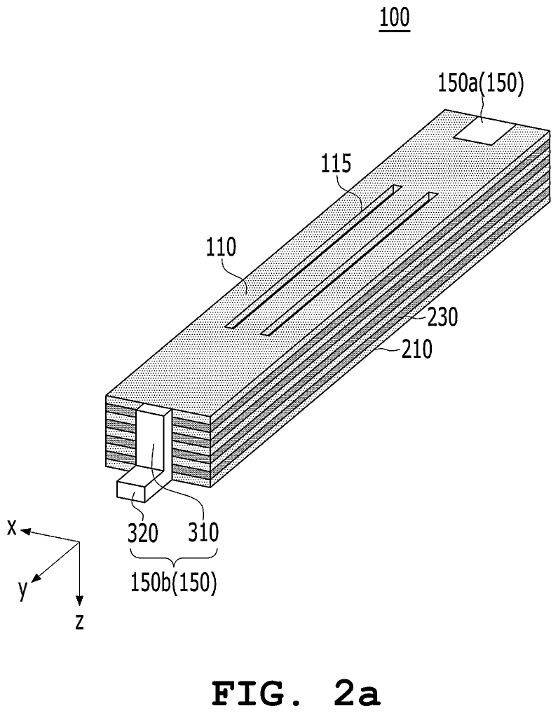

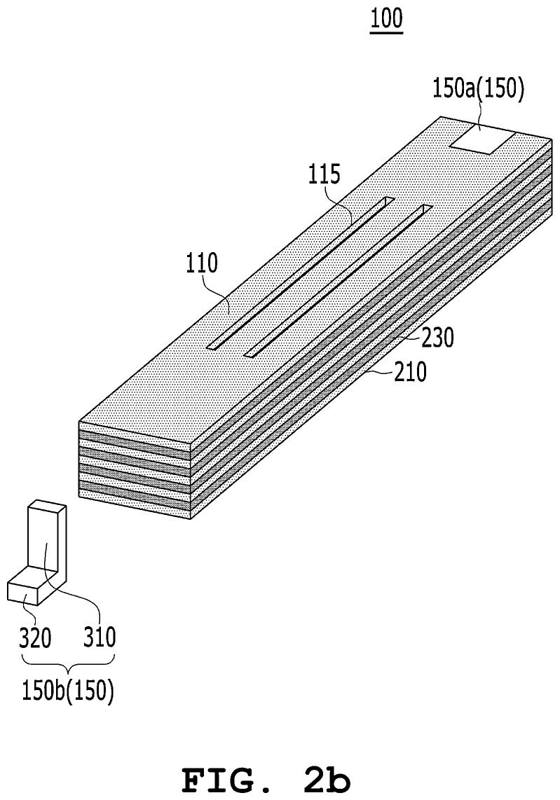

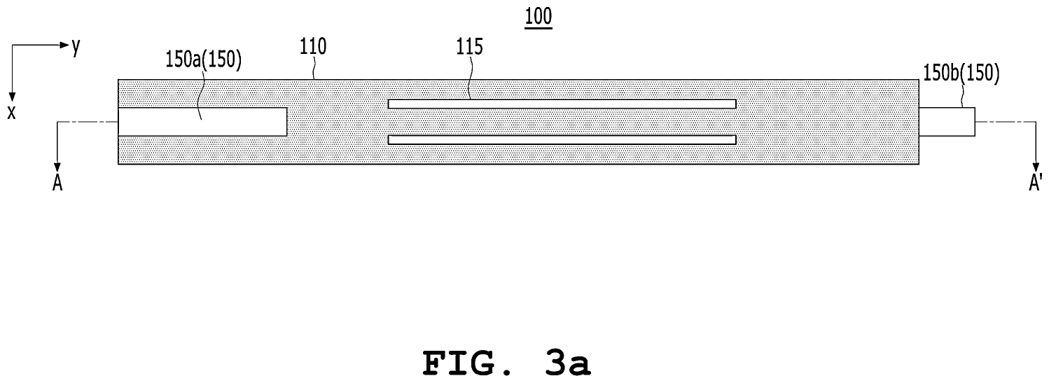

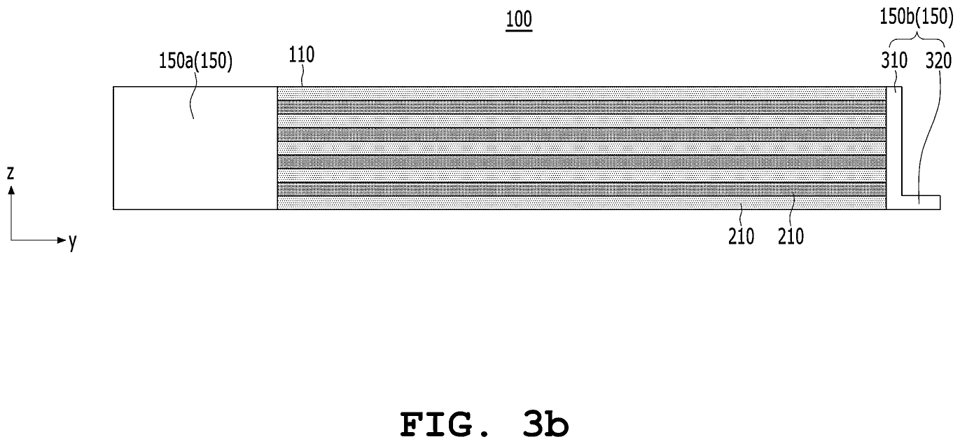

Hereinafter, an electrically conductive contact pin 100 according to the first embodiment of the present disclosure will be described with reference to FIGS. 1 to 3. FIG. 1a is a front perspective view illustrating the electrically conductive contact pin according to the first embodiment of the present disclosure. FIG. 1b is an exploded front perspective view illustrating a tip portion at a first end of the electrically conductive contact pin according to the first embodiment of the present disclosure. FIG. 2a is a rear perspective view illustrating the electrically conductive contact pin according to the first embodiment of the present disclosure. FIG. 2b is an exploded rear perspective view illustrating a tip portion at a second end of the electrically conductive contact pin according to the first embodiment of the present disclosure. FIG. 3a is a plan view illustrating the electrically conductive contact pin according to the first embodiment of the present disclosure. FIG. 3b is a sectional view taken along line A-A of FIG. 3a.

The electrically conductive contact pin 100 according to the first embodiment of the present disclosure includes a body portion 110 formed by stacking a plurality of metal layers, and a tip portion 150 located at an end of the body portion 110.

The body portion 110 has a structure in which the plurality of metal layers including a first metal 210 and a second metal 230 are stacked. Each stacked metal layer has a planar shape. The stacking direction of the plurality of metal layers including the first metal 210 and the second metal 230 corresponds to the height direction (z-direction) of the body portion 110. Each metal layer in a planar shape on the x-y plane is stacked in the height direction (z-direction) to form the body portion 110. Referring to FIGS. 1a and 1b, a plurality of first metals 210 are stacked in five layers and a plurality of second metals 230 are stacked in four layers, so that the body portion 110 is composed of nine metal layers stacked.

The first metals 210 may be made of a metal with relatively high wear resistance or hardness compared to the second metals 230, and the second metals 230 may be made of a metal with relatively high electrical conductivity compared to the first metals 210.

The first metals 210 may be made of a metal selected from the group consisting of rhodium (Rd), platinum (Pt), iridium (Ir), palladium (Pd), and an alloy of these metals; the group consisting of a palladium-cobalt (PdCo) alloy and a palladium-nickel (PdNi) alloy; or the group consisting of a nickel-phosphor (NiPh) alloy, a nickel-manganese (NiMn), a nickel-cobalt (NiCo), and a nickel-tungsten (NiW) alloy.

The second metals 230 may be made of a metal selected from the group consisting of copper (Cu), silver (Ag), gold (Au), and an alloy of these metals.

However, the first and second metals 210 and 230 may include metals other than the above-mentioned metals and are not limited to the above-mentioned exemplary materials.

Since the body portion 110 is composed of the plurality of metal layers stacked, the current carrying capacity of the electrically conductive contact pin 100 can be improved by controlling the content of metal with high electrical conductivity.

The electrically conductive contact pin 100 according to the first embodiment of the present disclosure facilitates transmission of high-frequency signals of 1 GHZ or higher.

Since the body portion 110 is composed of the plurality of metal layers stacked, each second metal 230 stacked has a thinner thickness compared to a second metal 230 made of a single material. In the case of the second metal 230 made using a single material rather than a multi-stage stacking method, when a high-frequency signal is transmitted, it flows on surfaces of the second metal 230 to a depth equal to the skin depth due to the skin effect, resulting in an area inside the second metal 230 where the signal is not transmitted.

However, according to the first embodiment of the present disclosure, when the electrically conductive contact pin 100 transmits a high-frequency signal, a larger amount of current flows through the second metals 230, which have higher electrical conductivity than the first metals 210, and the current flowing through each second metal 230 flows in a larger amount through surfaces of the second metal 230 than through an inside of the second metal 230 due to a skin effect. Here, due to the second metals 230 having a thin thickness and the skin effect on each second metal 230, the number of transmission paths for the high-frequency signal is increased. This makes it possible to maximize the current density inside the second metal 230 by minimizing an area of the second metal 230 that is not used for signal transmission. With this, electrical properties of the electrically conductive contact pin 100 can be improved.

As described above, by forming the body portion 110 by alternately stacking the second metals 230, which have a relatively high electrical conductivity compared to the first metals 210, and the first metals 210, which have a relatively low electrical conductivity compared to the second metals 230, the electrically conductive contact pin 100 according to the present disclosure can be advantageous for measuring high-frequency signals of 1 GHz or higher. Here, the high-frequency signals may have a frequency of 1 GHz to 20 GHz. However, the present disclosure is not limited thereto.

The first metals 210 form outer surfaces of the body portion 110. In order to improve wear resistance of the electrically conductive contact pin 100, the top and bottom layers of the body portion 110 are formed by the first metals 210. The second metals 230 are located inside the body portion 110.

The plurality of metal layers constituting the body portion 110 have a structure in which a first metal 210, a second metal 230, and a first metal 210 are sequentially stacked from the bottom. For example, the body portion 110 may be formed by alternately stacking the first metal 210, the second metal 230, and the first metal 210 in the order of a palladium-cobalt (PdCo) alloy, a copper (Cu), and a palladium-cobalt (PdCo) alloy; or by alternately stacking the first metal 210, the second metal 230, and the first metal 210 in the order of nickel (Ni), copper (Cu), and nickel (Ni). Alternatively, the body portion 110 may be formed by alternately stacking the first metal 210, the second metal 230, and the first metal 210 in the order of a palladium-cobalt (PdCo) alloy, copper (Cu), nickel (Ni), copper (Cu), and a palladium-cobalt (PdCo) alloy.

The plurality of metal layers may include at least three layers. In other words, the plurality of metal layers may include three or more odd-numbered layers or even-numbered layers. However, the number of the metal layers is not limited thereto.

The tip portion 150 is provided at the end of the body portion 110. The tip portion 150 is provided at least one end of the body portion 110. The tip portion 150 may have the same height as the body portion 110.

The tip portion 150 may be made of a metal of a different material from the materials of the metal layers constituting the body portion 110, or may be made of a metal of the same material as the material of at least one of the metal layers constituting the body portion 110. For example, when the body portion 110 is formed by alternately stacking a nickel-cobalt (NiCo) alloy and copper (Cu), the tip portion 150 may be made of rhodium (Rd), which is different from the materials of the metal layers constituting the body portion 110, or may be made of a nickel-cobalt (NiCo) alloy or copper (Cu), which is one of the materials of the metal layers constituting the body portion 110.

The tip portion 150 may be composed of a single metal layer or may be composed of a plurality of metal layers stacked. The tip portion 150 may be made of at least one metal selected from the group consisting of rhodium (Rd), platinum (Pt), iridium (Ir), palladium (Pd), and an alloy of these metals; the group consisting of a palladium-cobalt (PdCo) alloy and a palladium-nickel (PdNi) alloy; the group consisting of a nickel-phosphor (NiPh) alloy, a nickel-manganese (NiMn), a nickel-cobalt (NiCo), and a nickel-tungsten (NiW) alloy; or the group consisting of copper (Cu), silver (Ag), gold (Au), and an alloy of these metals. When considering wear resistance of the tip portion 150, the tip portion 150 may be made of a metal selected from the group consisting of rhodium (Rd), platinum (Pt), iridium (Ir), palladium (Pd), and an alloy of these metals; the group consisting of a palladium-cobalt (PdCo) alloy and a palladium-nickel (PdNi) alloy; or the group consisting of a nickel-phosphor (NiPh) alloy, a nickel-manganese (NiMn), a nickel-cobalt (NiCo), and a nickel-tungsten (NiW) alloy. Meanwhile, when considering electrical conductivity of the tip portion 150, the tip portion 150 may be made of a metal selected from the group consisting of copper (Cu), silver (Ag), gold (Au), and an alloy of these metals. However, the material of the tip portion 150 is not limited thereto.

The tip portion 150 is located at the end of the body portion 110 and is in contact with the plurality of metal layers constituting the body portion 110 at joint interfaces between the tip portion 150 and the body portion 110. At the joint interfaces, the plurality of metal layers is provided in the height direction (z-direction) of the body portion 110, and the tip portion 150 is in contact with the plurality of metal layers provided in the height direction of the body portion 110.

When measuring high-frequency signal using the electrically conductive contact pin 100 according to the embodiment of the present disclosure, a larger amount of current flows through the tip portion 150 to the second metals 230 than to the first metals 210 at the joint interfaces between the tip portion 150 and the body portion 110. The tip portion 150 functions as a distribution layer that allows the high-frequency signal to be uniformly transmitted between an object (not illustrated) and the body portion 110 to the plurality of second metals 230 of the body portion 110. The tip portion 150 made of a single material is in contact with the plurality of metal layers of the body portion 110 in the height direction of the tip portion 150, and allows a uniform current to flow along the surfaces of each second metal 230 provided in the height direction.

As the high-frequency signal flowing through each second metal 230 flows in a larger amount through the surfaces of the second metal 230 than the inside of the second metal 230 due to the skin effect, and the thickness of the second metal 230 becomes thinner through the stacked structure of the first metal 210 and the second metal 230, it is possible to maximize the available current density across the cross-section of the second metal 230. This facilitates transmission of the high-frequency signal.

Unlike the first embodiment of the present disclosure, when the tip portion 150 is in contact with a body portion 110 formed by stacking a plurality of metal layers made of a single material in the height direction, a high-frequency signal flows along the outermost surfaces of the body portion 110 to a depth equal to the skin depth, and there exists an area inside the body 110 where no current flows.

However, according to the first embodiment of the present disclosure, with the configuration in which the thickness (height) of each second metal 230 is made thin by the plurality of metal layers, most of the thickness area of the second metal 230 becomes an area where the high-frequency signals flow. This enables the high-frequency signal to be transmitted through the entire thickness area of the second metal 230.

Since the tip portion 150 is made of a single material and is provided in a bulk form, the high-frequency signal flows on surfaces of the tip portion 150 to a depth equal to the skin depth. The high-frequency signal flowing along the surfaces of the tip portion 150 is uniformly distributed to the plurality of second metals 230 at the joint interfaces between the tip portion 150 and the body portion 110 and flows along the surfaces of the second metals 230, thereby facilitating transmission of the high-frequency signal.

The tip portion 150 may include a first tip portion 150a located at a first end of the body portion 110 and a second tip portion 150b located at a second end of the body portion 110.

First, the first tip portion 150a will be described with reference to FIGS. 1a and 1b.

The first tip portion 150a is provided at the first end of the body portion 110. The first tip portion 150a is in contact with the plurality of metal layers constituting the body portion 110 at joint interfaces between the first tip portion 150a and the body portion 110.

The first tip portion 150a has the same height as the body portion 110. Therefore, the first tip portion 150a is in contact with all the plurality of metal layers stacked in the height direction (z-direction) of the body portion 110.

A recess portion 120 is provided at the first end of the body portion 110, and the first tip portion 150a is provided in the recess portion 120. The recess portion 120 is provided in a shape concaved from a first end surface 111b in the length direction (y-direction) of the body portion 110. In an inner area of the recess portion 120, the body portion 110 has inner side surfaces 111a where the plurality of metal layers stacked is exposed. First end surfaces 111b of the body portion 110 are located at opposite sides of the recess portion 120. In other words, the recess portion 120 is located between the first end surfaces 111b of the body portion 110. Since the body portion 110 is composed of the plurality of metal layers stacked in the height direction (z-direction), the metal layers exposed on the inner side surfaces 111a also have a stacked shape in the height direction (z-direction).

The first tip portion 150a has an upper surface, a lower surface, and outer side surfaces 151 connecting the upper surface and the lower surface to each other. In a structure in which the first tip portion 150a is embedded in the recess portion 120 of the body portion 110, the inner side surfaces 111a of the body portion 110 and the outer side surfaces 151 of the tip portion 150 are joined in opposed face-to-face relationship. The joint interfaces where the body portion 110 and the tip portion 150 are in opposed face-to-face relationship become vertical planes orthogonal to the planar metal layers. On the vertical planes where the body portion 110 and the first tip portion 150a are in opposed face-to-face relationship, the outer side surfaces 151 of the first tip portion 150a are in contact with all the plurality of metal layers constituting the body portion 110.

As illustrated in FIGS. 1a and 1b, When the first tip portion 150a has a rectangular parallelepiped shape, three outer side surfaces 151 of the first tip portion 150a are opposed face-to face to the inner side surfaces 111a of the body portion 110, and each outer side surface 151 is in contact with the plurality of metal layers constituting the body portion 110. The first tip portion 150a does not protrude from the first end of the body portion 110. In other words, the first end surfaces 111b and an exposed outer side surface of the first tip portion 150a form one plane at the first end of the electrically conductive contact pin 100.

At the first end of the body portion 110, a first end surface 111b of the body portion 110, the tip portion 150, and a first end surface of the body portion 110 are sequentially arranged in the width direction (x-direction) of the body portion 110. Meanwhile, the shape of the first tip portion 150a is not limited to a rectangular parallelepiped shape, and may include a cylindrical shape and a polyhedral shape.

Next, the second tip portion 150b will be described with reference to FIGS. 2a and 2b.

The second tip portion 150b is provided at the second end of the body portion 110. The second tip portion 150b is in contact with the plurality of metal layers constituting the body portion 110 at a joint interface between the second tip portion 150b and the body portion 110.

The second tip portion 150b is different from the first tip portion 150a in that it is not embedded inside the body portion 110 but is in contact with a second end surface 111c.

The second tip portion 150b includes a first portion 310 in contact the with plurality of metal layers constituting the body portion 110 at the joint interface between the second tip portion 150b and the body portion 110, and a second portion 320 formed at the first portion 310 and coming into contact with the object. The first portion 310 and the second portion 320 may be made of the same material or may be made of different materials.

The first portion 310 has the same height as the body portion 110. Therefore, the first portion 310 is in contact with all the plurality of metal layers stacked in the height direction (z-direction) of the body portion 110.

The second portion 320 may have a different height from the body portion 110. For example, as illustrated in FIGS. 2a and 2b, the height of the second portion 320 may be lower than that of the body portion 110, or may be higher than that of the body portion 110. The length of the second portion 320 in the width direction (x-direction) may be the same as the length of the first portion 310 in the width direction. When the electrically conductive contact pin 100 is viewed from the side, the second tip portion 150b has a “L” shape as illustrated in FIG. 3.

The body portion 110 extends long along its longitudinal direction (y-direction) and includes an empty hole 115 therein. The plurality of metal layers constituting the body portion 110 are exposed through the hole 115. The body portion 110 has a structure in which the second metals 230 stacked, which have relatively high electrical conductivity compared to the first metals 210, and each second metal 230 has a planar shape. As the hole 115 is formed, excessive contact pressure is not caused even when the length of the body portion 110 is shortened. With provision of the hole 115, it is possible to shorten the length of the body portion 110, which is advantageous for transmitting high-frequency signals.

At least one tip portion 150 among the first tip portion 150a and the second tip portion 150b removes an oxide film of the object while being moved horizontally in the width direction (x-direction) due to an external force applied to each end thereof in the longitudinal direction (y-direction).

At least one tip portion 150 of the first tip portion 150a and/or the second tip portion 150b has a length in the range of 100 μm to 400 μm. The electrically conductive contact pin 100 may be used by being inserted into a guide plate of a probe card. In this case, an end of the electrically conductive contact pin 100 protrudes from the bottom of the guide plate (lower guide plate). When the electrically conductive contact pin 100 is used for a long period of time and a number of times in this state, foreign substances stick to the end. To remove the foreign substances, a process of grinding the end is performed. Due to the process of grinding the end, the length of the electrically conductive contact pin 100 is shortened. A protruding length of the electrically conductive contact pin 100 from the bottom of the guide plate (lower guide plate) is preferably in the range of 100 μm to 400 μm. When the protruding length becomes less than 100 μm as a result of the grinding process, the electrically conductive contact pin 100 is replaced with a new one. With the configuration in which the length of the tip portion 150 ranges from 100 μm to 400 μm, even when the end is ground in the range of 100 μm to 400 μm, it is possible to make the tip portion 150 exist at the end. Thus, the function of the tip portion 150 can be maintained.

In performing the grinding process, when the tip portion 150 no longer exists, it is preferable to replace the electrically conductive contact pin 100 with a new one. The length of the remaining tip portion 150 can be confirmed through the appearance of the second stacked portion 120 exposed on a side surface of the electrically conductive contact pin 100. Therefore, with provision of the tip portion 150, it is possible to check the replacement time of the electrically conductive contact pin 100.

Meanwhile, hundreds to thousands of guide holes are formed in the guide plate. The electrically conductive contact pin 100 is inserted into each guide hole. The tip portion 150 has a width in the range of 10 μm to 40 μm in consideration of manufacturing tolerance of the guide holes of the guide plate and alignment error between the electrically conductive contact pin 100 and the object. With this range, it is possible to enable the tip portion 150 to make contact with the object even when a horizontal position error occurs between the end of the electrically conductive contact pin 100 and the object.

The first tip portion 150a may be a part that comes into contact with the object. Therefore, the first tip portion may be made of a metal with high wear resistance or hardness. For example, the first tip portion 150a may be made of a material with higher hardness than the second metals 230 constituting the body portion 110. This makes it possible to improve the wear resistance or hardness properties at the end of the electrically conductive contact pin 100 and at the same time increase the content of a metal with high electrical conductivity in the body portion 110 of the electrically conductive contact pin 100, thereby improving current carrying capacity.

The second tip portion 150b may be a part that comes into contact with a pad of an inspection apparatus. Therefore, the second tip portion 150b may be made of a metal with high electrical conductivity. For example, the second tip portion 150b may be made of a material with higher electrical conductivity than the first metals 210 constituting the body portion 110. With this, contact resistance can be reduced, thereby improving inspection reliability of the electrically conductive contact pin 100.

On the other hand, the first tip portion 150a and the second tip portion 150b may be made of the same metal material. For example, both the first tip portion 150a and the second tip portion 150b may be made of a palladium-cobalt (PdCo) alloy or copper (Cu). However, the present disclosure is not limited thereto, and any material that can improve the electrical, physical, and/or chemical properties of the electrically conductive contact pin 100 will be included as an embodiment of the present disclosure.

Hereinafter, a method of manufacturing the electrically conductive contact pin 100 according to the first embodiment of the present disclosure will be described. The method of manufacturing the electrically conductive contact pin 100 includes: forming a body portion 110 composed of a plurality of metal layers stacked in an inner space of a mold by plating; and forming an additional space in the mold at a position corresponding to an end of the body portion 110 and then forming a tip portion 150 in the additional space of the mold by plating. The mold may be made of an anodic aluminum oxide film, a photoresist, a silicon wafer, or a material similar thereto.

The step of forming the body portion 110 is to form the body portion 110 inside an open space of the mold by electroplating. Through electroplating, the plurality of metal layers including a plurality of first metals 210 and a plurality of second metals 230 are formed inside the open space. As a result, the body portion 110 is formed in a structure in which the plurality of metal layers including the first metals 210 and the second metals 230 are stacked, and each stacked metal layer has a planar shape.

After forming the body portion 110, the additional space is formed in the mold, and the tip portion 150 is formed in the additional space by electroplating. In the process of forming the tip portion 150, the tip portion 150 is integrated with the body portion 110 at the joint interfaces between the tip portion and the body portion 110.

### Second Embodiment

Next, the second embodiment according to the present disclosure will be described. However, the embodiments described below will be mainly described in terms of characteristic elements in comparison with the first embodiment, and descriptions of the same or similar elements to the first embodiment will be omitted.

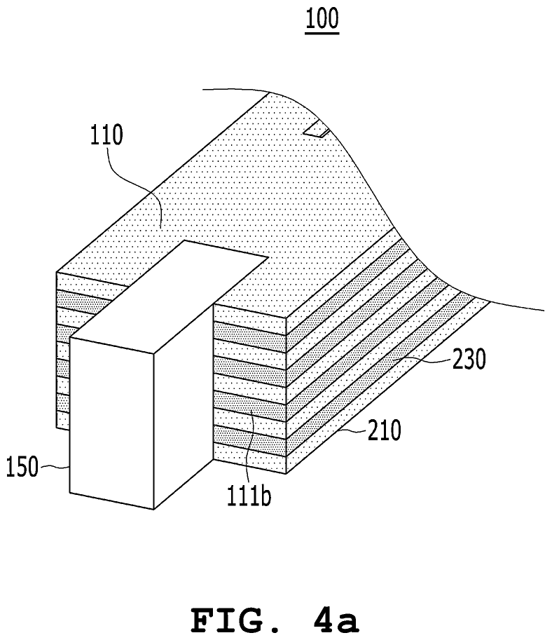

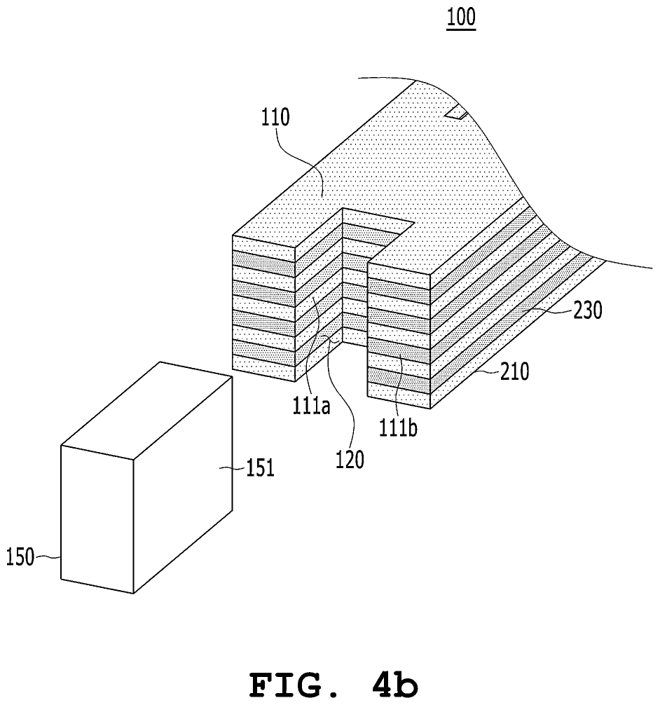

Hereinafter, an electrically conductive contact pin 100 according to the second embodiment of the present disclosure will be described with reference to FIGS. 4a and 4b. FIG. 4a is a perspective view illustrating an end of the electrically conductive contact pin 100 according to the second embodiment of the present disclosure. FIG. 4b is an exploded perspective view illustrating a tip portion 150 illustrated in FIG. 4a. FIGS. 4a and 4b illustrate only a part of the electrically conductive contact pin 100.

The tip portion 150 according to the second embodiment may be a first tip portion 150a located at a first end of the electrically conductive contact pin 100, or a second tip portion 150b located at a second end of the electrically conductive contact pin 100.

The tip portion 150 of the electrically conductive contact pin 100 according to the second embodiment of the present disclosure is different from the first tip portion 150a and the second tip portion 150b of the electrically conductive contact pin 100 according to the first embodiment in that only a part of the tip portion 150 is embedded in a body portion 110.

The tip portion 150 according to the second embodiment is configured so that a part thereof protrudes outwardly in the longitudinal direction from first end surfaces 111b or a second end surface 111c. Therefore, when the tip portion 150 comes into contact with an object, an end surface of the body portion 110 does not make contact with the object. With this, durability of the electrically conductive contact pin 100 can be improved compared to the first tip portion 150a according to the first embodiment. In addition, since the part of the tip portion 150 is embedded in the body portion 110, rigidity can be improved compared to the second tip portion 150b according to the first embodiment.

### Third Embodiment

Next, the third embodiment according to the present disclosure will be described. However, the embodiments described below will be mainly described in terms of characteristic elements in comparison with the first embodiment, and descriptions of the same or similar elements to the first embodiment will be omitted.

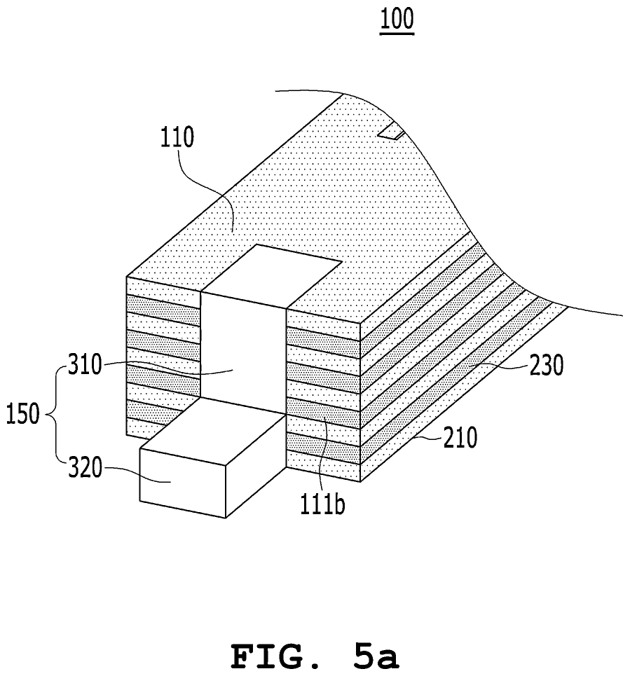

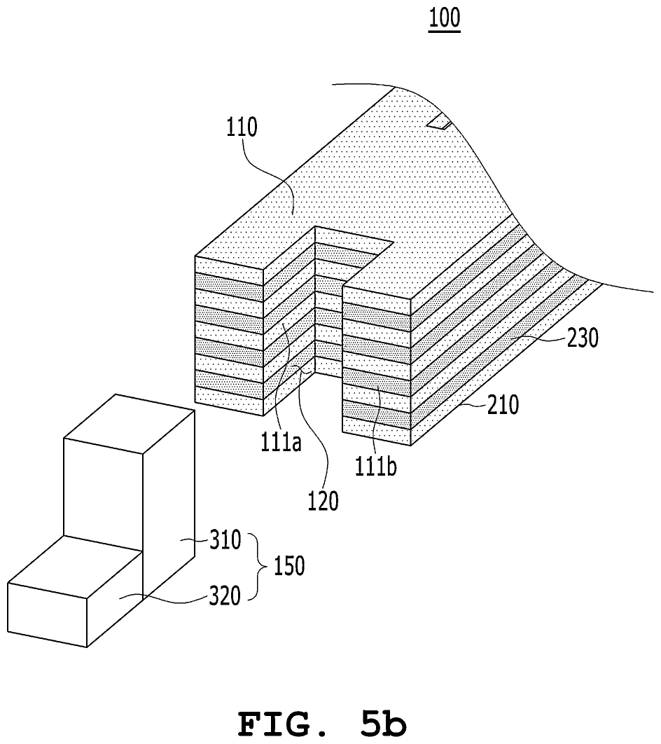

Hereinafter, an electrically conductive contact pin 100 according to the third embodiment of the present disclosure will be described with reference to FIGS. 5a and 5b. FIG. 5a is a perspective view illustrating an end of the electrically conductive contact pin 100 according to the third embodiment of the present disclosure. FIG. 5b is an exploded perspective view illustrating a tip portion 150 illustrated in FIG. 5a. FIGS. 5a and 5b illustrate only a part of the electrically conductive contact pin 100.

The tip portion 150 according to the third embodiment may be a first tip portion 150a located at a first end of the electrically conductive contact pin 100, or a second tip portion 150b located at a second end of the electrically conductive contact pin 100.

The tip portion 150 of the electrically conductive contact pin 100 according to the third embodiment of the present disclosure is different from the first tip portion 150a and the second tip portion 150b of the electrically conductive contact pin 100 according to the first embodiment in that the tip portion 150 includes a first portion 310 in contact with a plurality of metal layers constituting a body portion 110 at joint interfaces between the tip portion 150 and the body portion 110, and a second portion 320 formed at the first portion 310, having a lower height than the first portion 310, and coming into contact with an object; and the first portion 310 is embedded in the body portion 110.

Since the tip portion 150 according to the third embodiment is configured with the first portion 310 embedded in a recess portion 120 of the body portion 110, rigidity can be improved compared to the second tip portion 150b according to the first embodiment. In addition, when the tip portion 150 comes into contact with the object, an end surface of the body portion 110 does not make contact with the object. With this, durability of the electrically conductive contact pin 100 can be improved compared to the first tip portion 150a according to the first embodiment.

In addition, since the second portion 320 has a vertical cross-sectional area smaller than that of the first portion 310, contact pressure at the first portion 310 can be improved compared to the tip portion 150 according to the second embodiment.

### Fourth Embodiment

Next, the fourth embodiment according to the present disclosure will be described. However, the embodiments described below will be mainly described in terms of characteristic elements in comparison with the first embodiment, and descriptions of the same or similar elements to the first embodiment will be omitted.

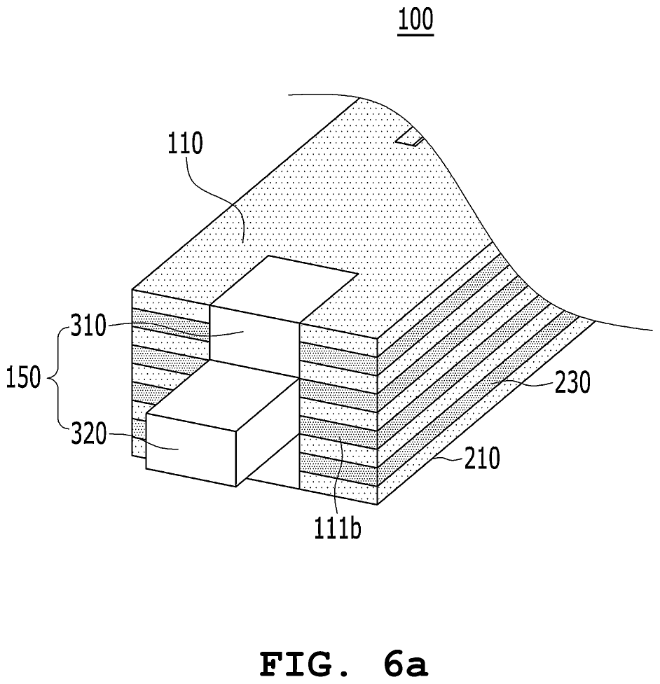

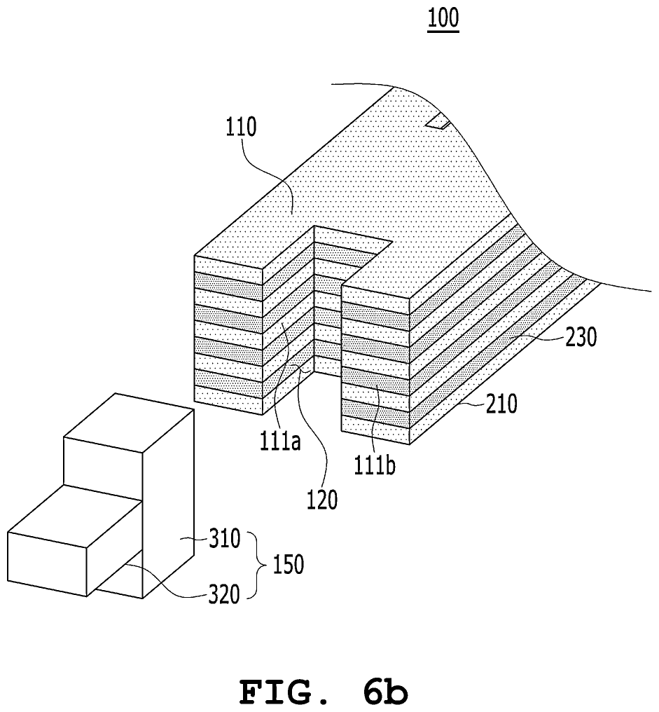

Hereinafter, an electrically conductive contact pin 100 according to the fourth embodiment of the present disclosure will be described with reference to FIGS. 6a and 6b. FIG. 6a is a perspective view illustrating an end of the electrically conductive contact pin 100 according to the fourth embodiment of the present disclosure. FIG. 6b is an exploded perspective view illustrating a tip portion 150 illustrated in FIG. 6a. FIGS. 6a and 6b illustrate only a part of the electrically conductive contact pin 100.

The tip portion 150 according to the fourth embodiment may be a first tip portion 150a located at a first end of the electrically conductive contact pin 100, or a second tip portion 150b located at a second end of the electrically conductive contact pin 100.

The tip portion 150 of the electrically conductive contact pin 100 according to the fourth embodiment of the present disclosure is different from the first tip portion 150a and the second tip portion 150b of the electrically conductive contact pin 100 according to the first embodiment in that the tip portion 150 includes a first portion 310 in contact with a plurality of metal layers constituting a body portion 110 at joint interfaces with the body portion 110, and a second portion 320 formed at the first portion 310, having a lower height than the first portion 310, and coming into contact with an object; and the first portion 310 is embedded in the body portion 110.

Since the tip portion 150 according to the fourth embodiment is configured with the first portion 310 embedded in a recess portion 120 of the body portion 110, rigidity can be improved compared to the second tip portion 150b according to the first embodiment. In addition, when the tip portion 150 comes into contact with the object, an end surface of the body portion 110 does not make contact with the object. With this, durability of the electrically conductive contact pin 100 can be improved compared to the first tip portion 150a according to the first embodiment.

In addition, unlike the tip portion 150 according to the third embodiment in which the second portion 310 is located eccentrically at a side of the first portion 310, the second portion 320 is located at a center of the first portion 310. With this, contact with the object is made at a center of the end of the electrically conductive contact pin 100, so that the bending moment caused by eccentricity can be minimized compared to the tip portion 150 according to the third embodiment.

### Fifth Embodiment

Next, the fifth embodiment according to the present disclosure will be described. However, the embodiments described below will be mainly described in terms of characteristic elements in comparison with the first embodiment, and descriptions of the same or similar elements to the first embodiment will be omitted.

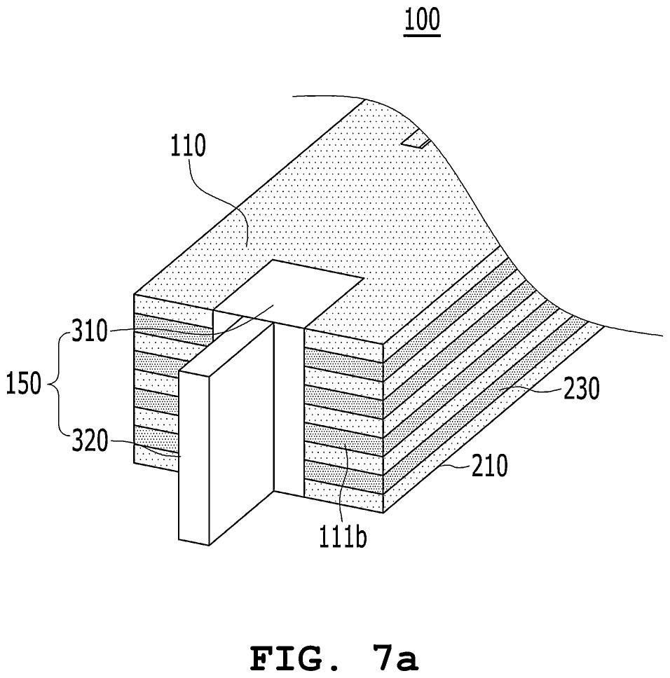

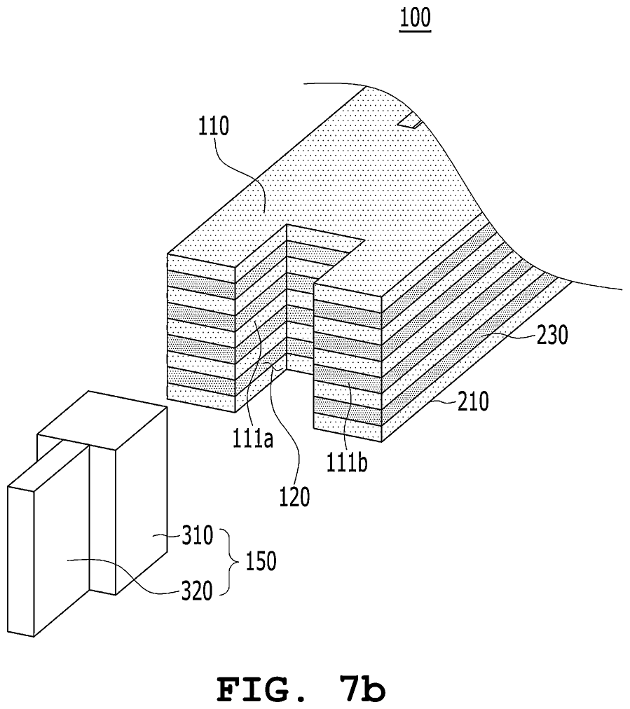

Hereinafter, an electrically conductive contact pin 100 according to the fifth embodiment of the present disclosure will be described with reference to FIGS. 7a and 7b. FIG. 7a is a perspective view illustrating an end of the electrically conductive contact pin 100 according to the fifth embodiment of the present disclosure. FIG. 7b is an exploded perspective view illustrating a tip portion 150 illustrated in FIG. 7a. FIGS. 7a and 7b illustrate only a part of the electrically conductive contact pin 100.

The tip portion 150 according to the fifth embodiment may be a first tip portion 150a located at a first end of the electrically conductive contact pin 100, or a second tip portion 150b located at a second end of the electrically conductive contact pin 100.

The tip portion 150 of the electrically conductive contact pin 100 according to the fifth embodiment of the present disclosure is different from the first tip portion 150a and the second tip portion 150b of the electrically conductive contact pin 100 according to the first embodiment in that the tip portion 150 includes a first portion 310 in contact with a plurality of metal layers constituting a body portion 110 at joint interfaces between the tip portion 150 and the body portion 110, and a second portion 320 formed at the first portion 310, having the same height as, but a narrower width than the first portion 310, and coming into contact with an object.

Since the tip portion 150 according to the fifth embodiment is configured with the first portion 310 embedded in a recess portion 120 of the body portion 110, rigidity can be improved compared to the second tip portion 150b according to the first embodiment. In addition, when the tip portion 150 comes into contact with an object, an end surface of the body portion 110 does not make contact with the object. With this, durability of the electrically conductive contact pin 100 can be improved compared to the first tip portion 150a according to the first embodiment.

In addition, unlike the tip portions 150 according to the third and fourth embodiments, the second portion 320 is located at a center of the first portion 310 and the width of the second portion 320 is smaller than that of the first portion 310. With this, when an oxide film is removed by the tip portion 150, it can be removed in a larger area.

### Sixth Embodiment

Next, the sixth embodiment according to the present disclosure will be described. However, the embodiments described below will be mainly described in terms of characteristic elements in comparison with the first embodiment, and descriptions of the same or similar elements to the first embodiment will be omitted.

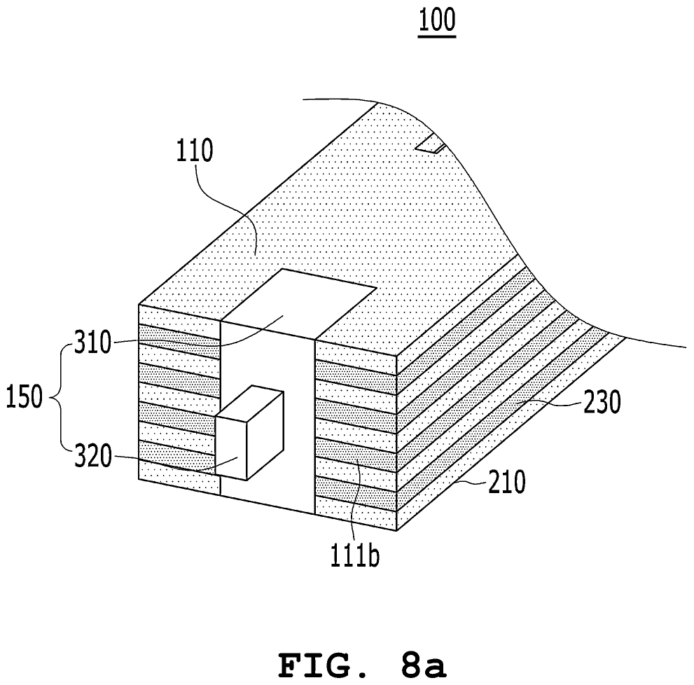

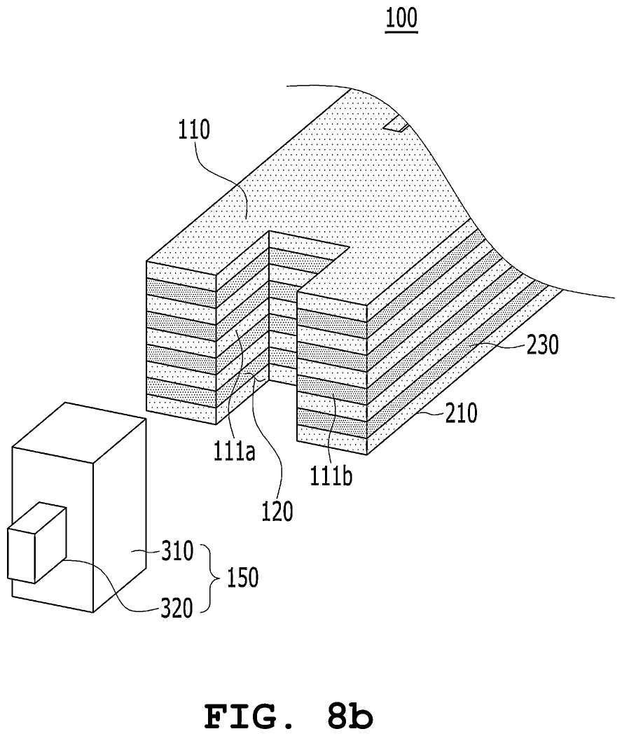

Hereinafter, an electrically conductive contact pin 100 according to the sixth embodiment of the present disclosure will be described with reference to FIGS. 8a and 8b. FIG. 8a is a perspective view illustrating an end of the electrically conductive contact pin 100 according to the sixth embodiment of the present disclosure. FIG. 8b is an exploded perspective view illustrating a tip portion 150 illustrated in FIG. 8a. FIGS. 8a and 8b illustrate only a part of the electrically conductive contact pin 100.

The tip portion 150 according to the sixth embodiment may be a first tip portion 150a located at a first end of the electrically conductive contact pin 100, or a second tip portion 150b located at a second end of the electrically conductive contact pin 100.

The tip portion 150 of the electrically conductive contact pin 100 according to the sixth embodiment of the present disclosure is different from the first tip portion 150a and the second tip portion 150b of the electrically conductive contact pin 100 according to the first embodiment in that the tip portion 150 includes a first portion 310 in contact with a plurality of metal layers constituting a body portion 110 at joint interfaces between the tip portion 150 and the body portion 110, and a second portion 320 formed at the first portion 310, having a lower height and a narrower width than the first portion 310, and coming into contact with an object.

Since the tip portion 150 according to the sixth embodiment is configured with the first portion 310 embedded in a recess portion 120 of the body portion 110, rigidity can be improved compared to the second tip portion 150b according to the first embodiment. In addition, when the tip portion 150 comes into contact with the object, an end surface of the body portion 110 does not make contact with the object. With this, durability of the electrically conductive contact pin 100 can be improved compared to the first tip portion 150a according to the first embodiment.

In addition, unlike the tip portions 150 according to the third and fourth embodiments, the second portion 320 is located at a center of the first portion 310 and the width and height of the second portion 320 are smaller than those of the first portion 310. With this, contact pressure at a center of the tip portion 150 can be improved.

### Seventh Embodiment

Next, the seventh embodiment according to the present disclosure will be described. However, the embodiments described below will be mainly described in terms of characteristic elements in comparison with the first embodiment, and descriptions of the same or similar elements to the first embodiment will be omitted.

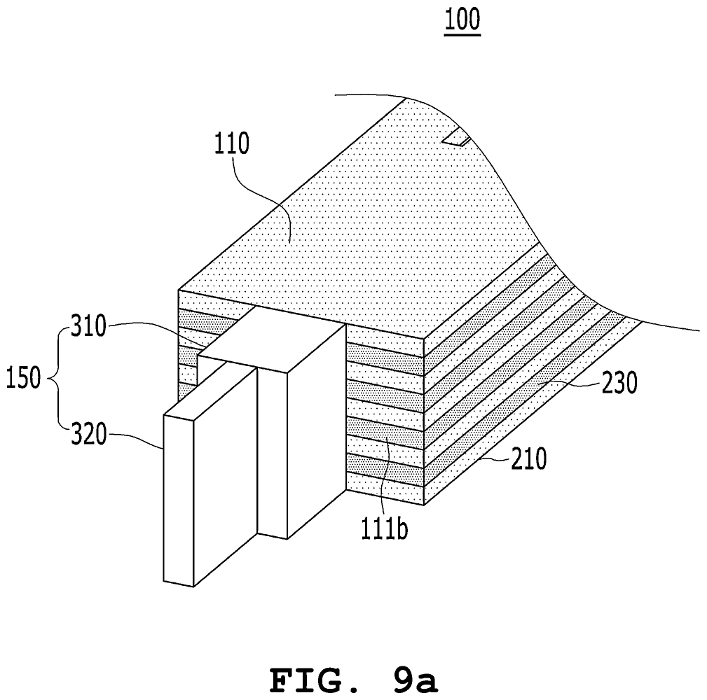

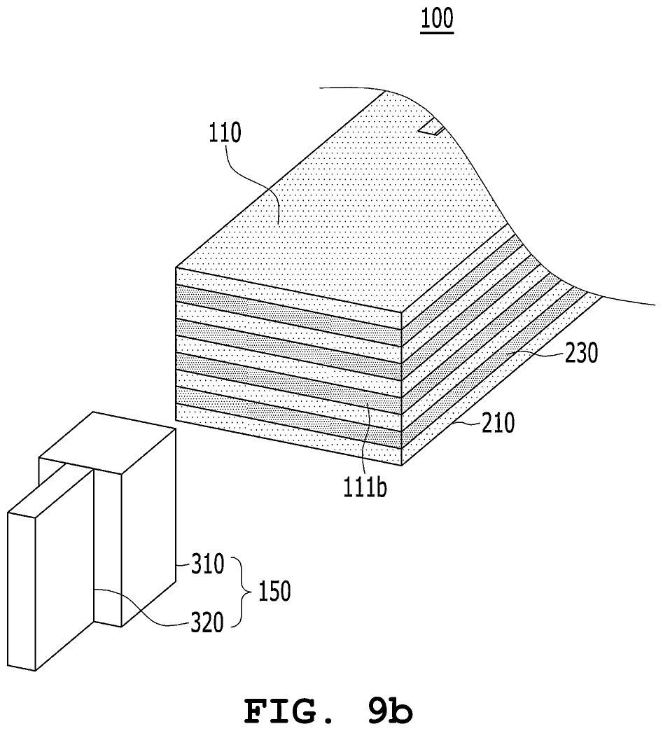

Hereinafter, an electrically conductive contact pin 100 according to the seventh embodiment of the present disclosure will be described with reference to FIGS. 9a and 9b. FIG. 9a is a perspective view illustrating an end of the electrically conductive contact pin 100 according to the seventh embodiment of the present disclosure. FIG. 9b is an exploded perspective view illustrating a tip portion 150 illustrated in FIG. 9a. FIGS. 9a and 9b illustrate only a part of the electrically conductive contact pin 100.

The tip portion 150 according to the seventh embodiment may be a first tip portion 150a located at a first end of the electrically conductive contact pin 100, or a second tip portion 150b located at a second end of the electrically conductive contact pin 100.

The tip portion 150 of the electrically conductive contact pin 100 according to the seventh embodiment of the present disclosure is different from the second tip portion 150b of the electrically conductive contact pin 100 according to the first embodiment in that the tip portion 150 includes a first portion 310 in contact with a plurality of metal layers constituting a body portion 110 at a joint interface between the tip portion 150 and the body portion 110, and a second portion 320 formed at the first portion 310, having the same height as the first portion 310, and coming into contact with an object.

With this, when an oxide film is removed by the tip portion 150, it can be removed in a larger area compared to the second portion 150b according to the first embodiment.

### Eighth Embodiment

Next, the eighth embodiment according to the present disclosure will be described. However, the embodiments described below will be mainly described in terms of characteristic elements in comparison with the first embodiment, and descriptions of the same or similar elements to the first embodiment will be omitted.

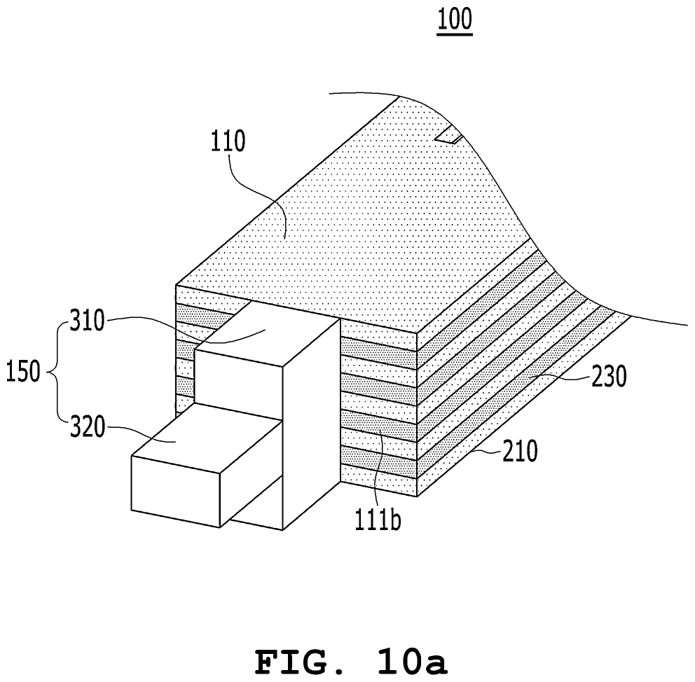

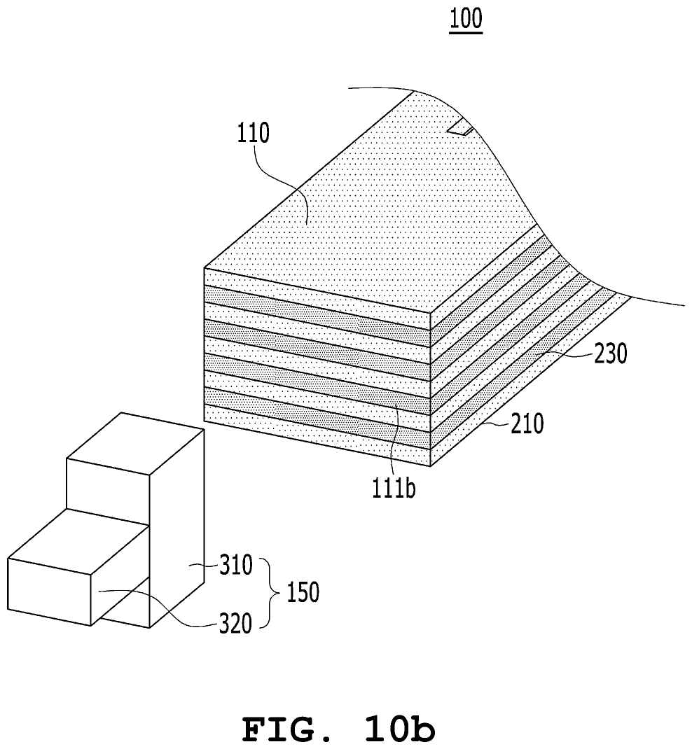

Hereinafter, an electrically conductive contact pin 100 according to the eighth embodiment of the present disclosure will be described with reference to FIGS. 10a and 10b. FIG. 10a is a perspective view illustrating an end of the electrically conductive contact pin 100 according to the eighth embodiment of the present disclosure. FIG. 10b is an exploded perspective view illustrating a tip portion 150 illustrated in FIG. 10a. FIGS. 10a and 10b illustrate only a part of the electrically conductive contact pin 100.

The tip portion 150 according to the eighth embodiment may be a first tip portion 150a located at a first end of the electrically conductive contact pin 100, or a second tip portion 150b located at a second end of the electrically conductive contact pin 100.

The tip portion 150 of the electrically conductive contact pin 100 according to the eighth embodiment of the present disclosure is different from the second tip portion 150b of the electrically conductive contact pin 100 according to the first embodiment in that the tip portion 150 includes a first portion 310 in contact with a plurality of metal layers constituting a body portion 110 at a joint interface between the tip portion 150 and the body portion 110, and a second portion 320 formed at a center of the first portion 310, having a lower height than the first portion 310, and coming into contact with an object.

With this, contact with the object is made at a center of the end of the electrically conductive contact pin 100, so that the bending moment caused by eccentricity can be minimized compared to the second tip portion 150b according to the first embodiment.

### Ninth Embodiment

Next, the ninth embodiment according to the present disclosure will be described. However, the embodiments described below will be mainly described in terms of characteristic elements in comparison with the first embodiment, and descriptions of the same or similar elements to the first embodiment will be omitted.

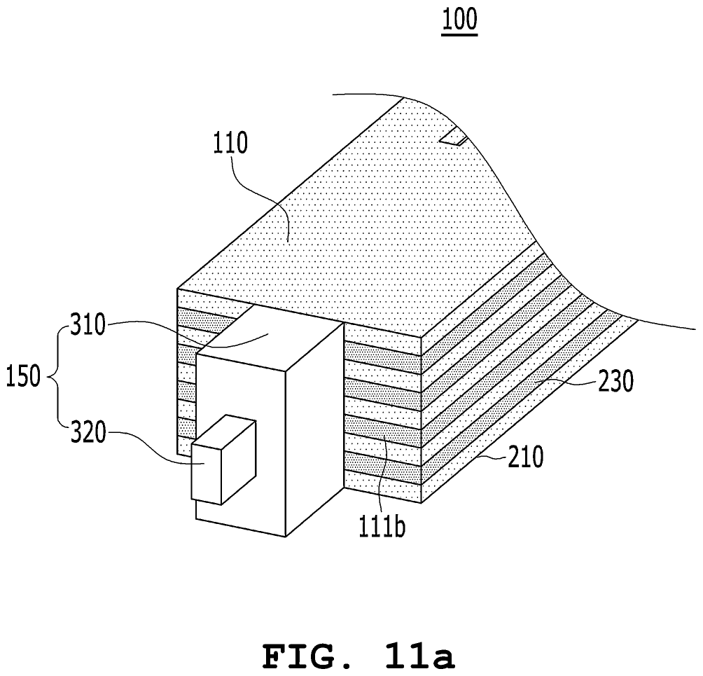

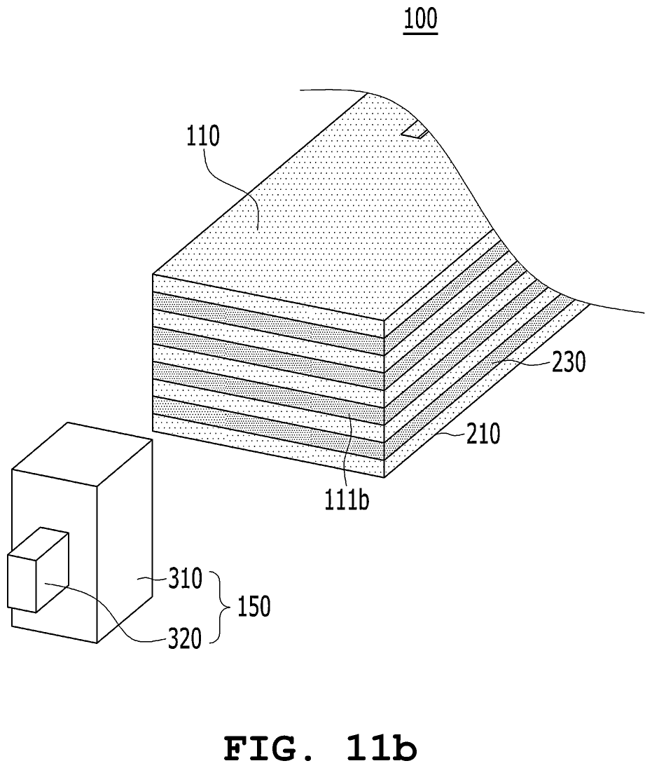

Hereinafter, an electrically conductive contact pin 100 according to the ninth embodiment of the present disclosure will be described with reference to FIGS. 11a and 11b. FIG. 11a is a perspective view illustrating an end of the electrically conductive contact pin 100 according to the ninth embodiment of the present disclosure. FIG. 11b is an exploded perspective view illustrating a tip portion 150 illustrated in FIG. 11a. FIGS. 11a and 11b illustrate only a part of the electrically conductive contact pin 100.

The tip portion 150 according to the ninth embodiment may be a first tip portion 150a located at a first end of the electrically conductive contact pin 100, or a second tip portion 150b located at a second end of the electrically conductive contact pin 100.

The tip portion 150 of the electrically conductive contact pin 100 according to the ninth embodiment of the present disclosure is different from the second tip portion 150b of the electrically conductive contact pin 100 according to the first embodiment in that the tip portion 150 includes a first portion 310 in contact with a plurality of metal layers constituting a body portion 110 at a joint interface between the tip portion 150 and the body portion 110, and a second portion 320 formed at the first portion 310, having a lower height and a narrower width than the first portion 310, and coming into contact with an object.

In addition, unlike the second tip portion 150b according to the first embodiment, the second portion 320 is located at a center of the first portion 310 and the width and height of the second portion 320 are smaller than those of the first portion 310. With this, contact pressure at a center of the tip portion 150 can be improved compared to the second tip portion 150b according to the first embodiment.

As described above, the tip portion 150 may have the same height as the body portion 110. In addition, the tip portion 150 may be embedded in a recess portion formed in the body portion 110 so that three surfaces of the tip portion 150 are in contact with the body portion 110. In addition, the tip portion 150 may be embedded in the body portion 110 so that three surfaces thereof are exposed, and the tip portion 150 may not protrude from an end of the body portion 110. In addition, the tip portion 150 may be at least partially embedded in the body portion 110 so that at least three surfaces thereof are exposed.

Meanwhile, the tip portion 150 may include a first portion 310 in contact with the plurality of metal layers constituting the body portion 110 at a joint interface between the tip portion 150 and the body portion 110, and a second portion 320 formed at the first portion 310, having a lower height than the first portion 310, and coming into contact with the object.

Alternatively, the tip portion 150 may include a first portion 310 in contact with the plurality of metal layers constituting the body portion 110 at a joint interface between the tip portion 150 and the body portion 110, and a second portion 320 formed at the first portion 310, having the same height as, but a narrower width than the first portion 310, and coming into contact with the object.

Alternatively, the tip portion 150 may include a first portion 310 in contact with the plurality of metal layers constituting the body portion 110 at joint interfaces between the tip portion 150 and the body portion 110 and at least partially embedded in the body portion 110, and a second portion 320 formed at the first portion 310 and coming into contact with the object.

### Tenth Embodiment

Next, the tenth embodiment according to the present disclosure will be described. However, the embodiments described below will be mainly described in terms of characteristic elements in comparison with the first embodiment, and descriptions of the same or similar elements to the first embodiment will be omitted.

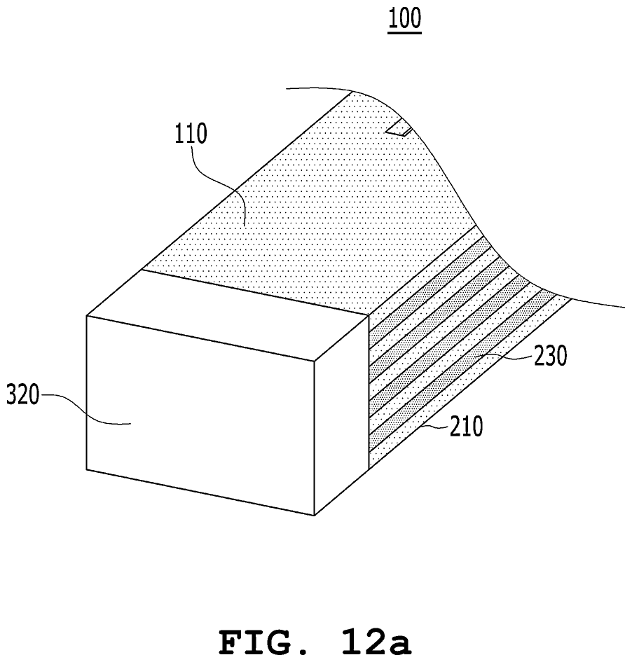

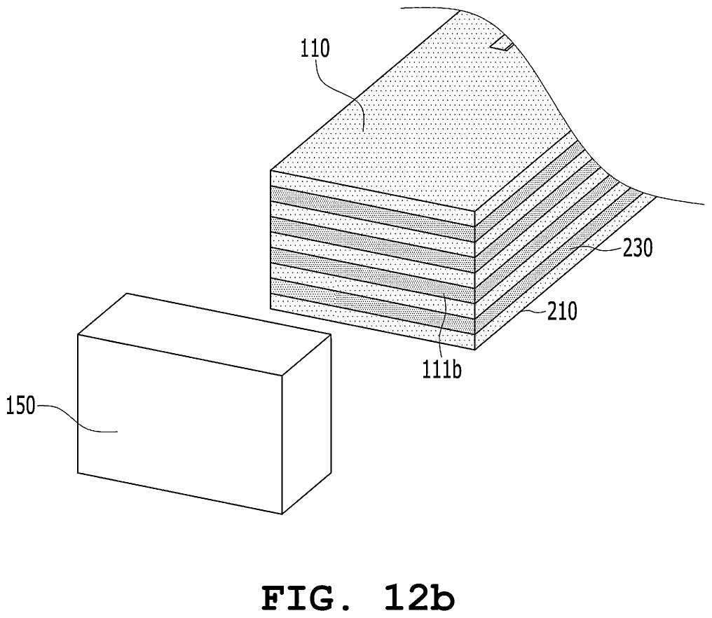

Hereinafter, an electrically conductive contact pin 100 according to the tenth embodiment of the present disclosure will be described with reference to FIGS. 12a and 12b. FIG. 12a is a perspective view illustrating an end of the electrically conductive contact pin 100 according to the tenth embodiment of the present disclosure. FIG. 12b is an exploded perspective view illustrating a tip portion 150 illustrated in FIG. 12a. FIGS. 12a and 12b illustrate only a part of the electrically conductive contact pin 100.

The tip portion 150 according to the tenth embodiment may be a first tip portion 150a located at a first end of the electrically conductive contact pin 100, or a second tip portion 150b located at a second end of the electrically conductive contact pin 100.

The tip portion 150 of the electrically conductive contact pin 100 according to the tenth embodiment of the present disclosure is different from the first portion 150a and the second tip portion 150b of the electrically conductive contact pin 100 according to the first embodiment in that the tip portion 150 is in contact with a plurality of metal layers constituting a body portion 110 at a joint interface between the tip portion 150 and the body portion 110 and has the same width as the body portion 110.

In other words, the tip portion 150 of the electrically conductive contact pin 100 according to the tenth embodiment is in contact with the plurality of metal layers constituting the body portion 110 at the joint interface between the tip portion 150 and the body portion 110, and the width and height of the tip portion 150 are the same as those of the body portion 110.

As a modification of the electrically conductive contact pin 100 according to the tenth embodiment, the tip portion 150 may include a first portion 310 in contact with the plurality of metal layers constituting the body portion 110 at a joint interface between the tip portion 150 and the body portion 110, and a second portion 320 formed at the first portion 310 coming into contact with an object. Here, the first portion 310 may have the same width and height as those of the body portion 110. In addition, the second portion 320 may have a narrower width and/or a lower height than the first portion 310, and the second portion 320 may be located eccentrically at a side of the first portion 310 or may be located at a center of the first portion 310.

### Eleventh Embodiment

Next, the eleventh embodiment according to the present disclosure will be described. However, the embodiments described below will be mainly described in terms of characteristic elements in comparison with the first embodiment, and descriptions of the same or similar elements to the first embodiment will be omitted.

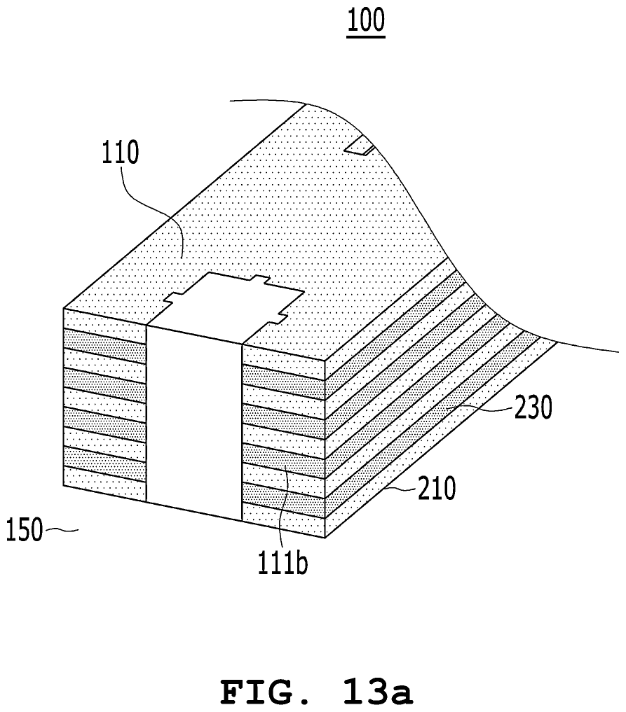

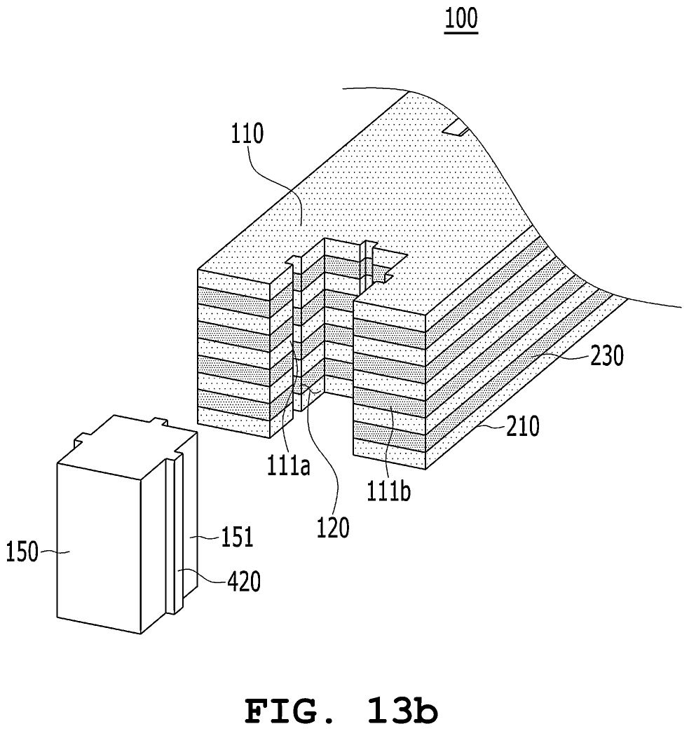

Hereinafter, an electrically conductive contact pin 100 according to the eleventh embodiment of the present disclosure will be described with reference to FIGS. 13a and 13b. FIG. 13a is a perspective view illustrating an end of the electrically conductive contact pin 100 according to the eleventh embodiment of the present disclosure. FIG. 13b is an exploded perspective view illustrating a tip portion 150 illustrated in FIG. 13a. FIGS. 13a and 13b illustrate only a part of the electrically conductive contact pin 100.

The tip portion 150 according to the eleventh embodiment may be a first tip portion 150a located at a first end of the electrically conductive contact pin 100, or a second tip portion 150b located at a second end of the electrically conductive contact pin 100.

The tip portion 150 of the electrically conductive contact pin 100 according to the eleventh embodiment of the present disclosure is different from the first portion 150a and the second tip portion 150b of the electrically conductive contact pin 100 according to the first embodiment in that the tip portion 150 is in contact with a plurality of metal layers constituting a body portion 110 at joint interfaces between the tip portion 150 the body portion 110 and is joined to the body portion 110 by a coupling reinforcement structure.

At each joint interface between the tip portion 150 and the body portion 110, the body portion 110 is provided with a first engaging portion 410, and the tip portion 150 is provided with a second engaging portion 420 coupled to the first engaging portion 410 to form a coupling reinforcement structure.

The first engaging portion 410 is provided at the body portion along the height direction of the joint interface, and the second engaging portion 420 is provided at the tip portion 150 along the height direction of the joint interface.

At each joint interface, the body portion 110 is provided with the first engaging portion 410, and the tip portion 150 is provided with the second engaging portion 420 coupled to the first engaging portion 410 to form a coupling reinforcement structure.

The first engaging portion 410 is provided on a recess portion 120 of the body portion 110. The first engaging portion 410 is provided in a shape recessed from each inner side surface 111a and extending along the height direction of the body portion 110. At least one first engaging portion 410 may be formed. In FIG. 13b, it is illustrated that one first engaging portion 410 is formed on each inner side surface 11a of the recess portion 120, but the present disclosure is not limited thereto. In addition, the cross-sectional shape of the first engaging portion 410 is not limited to a rectangular cross-sectional shape illustrated in the drawings, but includes any shape that can exert an anchoring effect.

The second engaging portion 420 is provided on each side surface of the tip portion 150 at a position corresponding to the first engaging portion 410 so as to be coupled to the first engaging portion 410. The second engaging portion 420 is provided in a shape protruding from each side surface of the tip portion 150 and extending along the height direction of the tip portion 150. The second engaging portion 420 is formed in the same number as the first engaging portion 410. The second engaging portion 420 is coupled to the first engaging portion 410 by shape engagement.

The first engaging portion 410 provided in the body portion 110 and the second engaging portion 420 provided in the tip portion 150 are coupled to each other to form a coupling reinforcement structure. With this, an anchoring effect is exerted between the tip portion 150 and the body portion 110, so that the tip portion 150 can be more firmly coupled to the body portion 110.

On the other hand, the body portion 110 may be provided with a second engaging portion 420 and the tip portion 150 may be provided with a first engaging portion 410 to form a coupling reinforcement structure.

The coupling reinforcement structure according to the eleventh embodiment can also be applied to the joint interfaces between the tip portion 150 and the body portion 110 of the electrically conductive contact pin 100 according to other embodiments.

### Twelfth Embodiment

Next, the twelfth embodiment according to the present disclosure will be described. However, the embodiments described below will be mainly described in terms of characteristic elements in comparison with the first embodiment, and descriptions of the same or similar elements to the first embodiment will be omitted.

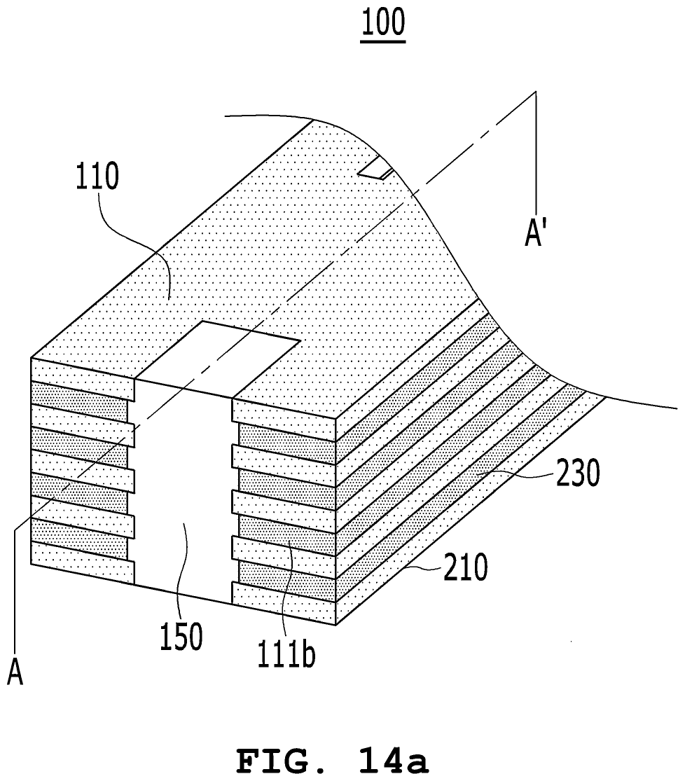

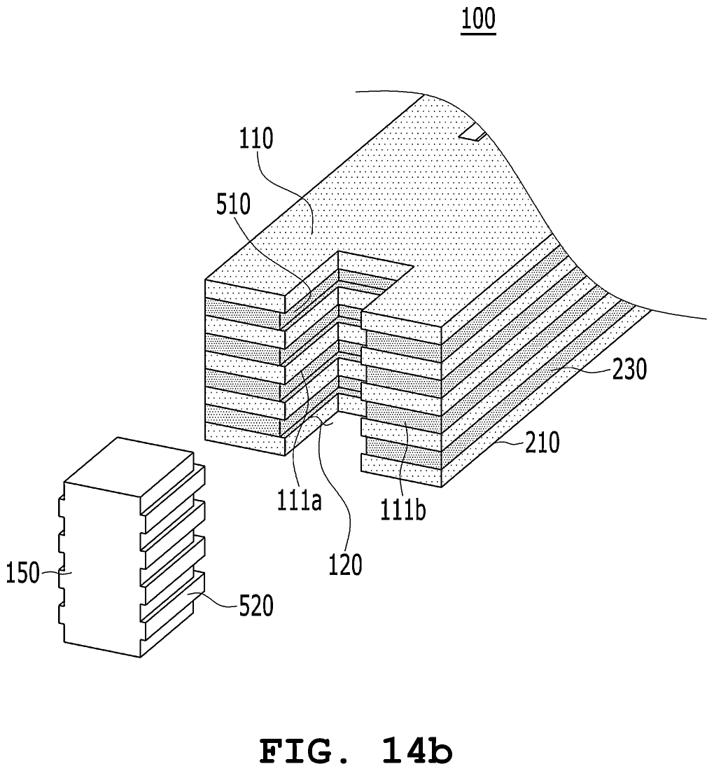

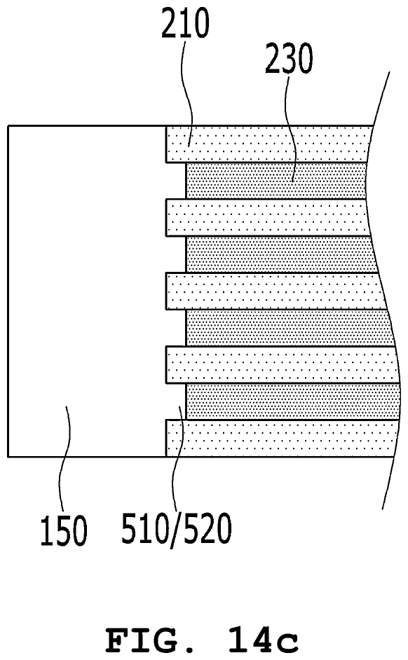

Hereinafter, an electrically conductive contact pin 100 according to the twelfth embodiment of the present disclosure will be described with reference to FIGS. 14a and 14b. FIG. 14a is a perspective view illustrating an end of the electrically conductive contact pin 100 according to the twelfth embodiment of the present disclosure. FIG. 14b is an exploded perspective view illustrating a tip portion 150 illustrated in FIG. 14a. FIGS. 14a and 14b illustrate only a part of the electrically conductive contact pin 100.

The tip portion 150 according to the twelfth embodiment may be a first tip portion 150a located at a first end of the electrically conductive contact pin 100, or a second tip portion 150b located at a second end of the electrically conductive contact pin 100.

The tip portion 150 of the electrically conductive contact pin 100 according to twelfth embodiment of the present disclosure is different from the first portion 150a and the second tip portion 150b of the electrically conductive contact pin 100 according to the first embodiment in that the tip portion 150 is in contact with a plurality of metal layers constituting a body portion 110 at joint interfaces between the tip portion 150 the body portion 110 and is joined to the body portion 110 by a coupling reinforcement structure.

At each joint interface between the tip portion 150 and the body portion 110, the body portion 110 is provided with a first engaging portion 410, and the tip portion 150 is provided with a second engaging portion 420 coupled to the first engaging portion 410 to form a coupling reinforcement structure.

The first engaging portion 410 is provided in the body portion 110 along the perimeter direction of the joint interface, and the second engaging portion 420 is provided in the tip portion 150 along the perimeter direction of the joint interface.

The first engaging portion 410 is provided on a recess portion 120 of the body portion 110. The first engaging portion 410 is provided in a shape recessed from each inner side surface 111a and extending along the perimeter direction of the inner side surface 111a.

Referring to FIG. 14c, the first engaging portion 510 is configured so that at least one layer among the plurality of metal layers constituting the body portion 110 relatively protrudes. With respect to one metal layer, adjacent metal layers thereabove and therebelow protrude at the joint interfaces to form the first engaging portion 410. When the body portion 110 is composed of the plurality of metal layers in which a plurality of first metals 210 and a plurality of second metals 230 are alternately stacked, the first metals 210 protrude relatively compared to the second metals 230 adjacent thereabove and therebelow at the joint interfaces, so that the first engaging portion 410 is provided between the first metals 210. This may be implemented by selectively etching the second metals 230 at the joint interfaces after forming the body portion 110 and before forming the tip portion 150.

The second engaging portion 520 is provided on each side surface of the tip portion 150 at a position corresponding to the first engaging portion 510. The second engaging portion 520 is provided in a shape protruding from the side surface of the tip portion 150 and extending along the perimeter direction of the tip portion 150. The second engaging portion 520 is formed in the same number as the first engaging portion 510.

The first engaging portion 510 provided in the body portion 110 and the second engaging portion 520 provided in the tip portion 150 are coupled to each other to form a coupling reinforcement structure. With this, the tip portion 150 can be more firmly coupled to the body portion 110.

The coupling reinforcement structure according to the twelfth embodiment can also be applied to the joint interfaces between the tip portion 150 and the body portion 110 of the electrically conductive contact pin 100 according to other embodiments.

The electrically conductive contact pin 100 according to each exemplary embodiment of the present disclosure described above is provided in an inspection apparatus and is used to transmit electrical signals by making electrical and physical contact with an object. The inspection apparatus may be an inspection apparatus used in a semiconductor manufacturing process, for example, a probe card or a test socket. The electrically conductive contact pin 100 according to each exemplary embodiment of the present disclosure may be a probe pin provided in the probe card or a socket pin provided in the test socket. However, the present disclosure is not limited thereto, and includes any pin for checking whether the object is defective by applying electricity.

Although the exemplary embodiments of the present disclosure have been described for illustrative purposes, those skilled in the art will appreciate that various modifications, additions, and substitutions are possible, without departing from the scope and spirit of the present disclosure as disclosed in the accompanying claims.

### DESCRIPTION OF THE REFERENCE NUMERALS IN THE DRAWINGS

100: electrically conductive contact pin
110: body portion
150: tip portion
210: first metal
230: second metal
310: first portion
320: second portion

1. An electrically conductive contact pin, comprising:
a body portion formed by stacking a plurality of metal layers; and
a tip portion located at an end of the body portion, and in contact with the plurality of metal layers constituting the body portion at joint interfaces between the tip portion and the body portion.

2. The electrically conductive contact pin of claim 1, wherein the body portion includes:
a first metal; and
a second metal,
wherein the first metal forms an outer surface of the body portion, and
the second metal is located inside the body portion.

3. The electrically conductive contact pin of claim 1, wherein the body portion includes:
a first metal; and
a second metal,
wherein the first metal (210) is made of a metal selected from the group consisting of rhodium (Rd), platinum (Pt), iridium (Ir), palladium (Pd), and an alloy of these metals; the group consisting of a palladium-cobalt (PdCo) alloy and a palladium-nickel (PdNi) alloy; or the group consisting of a nickel-phosphor (NiPh) alloy, a nickel-manganese (NiMn), a nickel-cobalt (NiCo), and a nickel-tungsten (NiW) alloy, and
the second metal (230) is made of a metal selected from the group consisting of copper (Cu), silver (Ag), gold (Au), and an alloy of these metals.

4. The electrically conductive contact pin of claim 1, wherein the tip portion has the same height as the body portion.

5. The electrically conductive contact pin of claim 1, wherein the tip portion is embedded in a recess portion formed in the body portion so that three surfaces of the tip portion are in contact with the body portion.

6. The electrically conductive contact pin of claim 1, wherein the tip portion is embedded in the body portion so that three surfaces thereof are exposed, and
the tip portion does not protrude from the end of the body portion.

7. The electrically conductive contact pin of claim 1, wherein the tip portion is at least partially embedded in the body portion so that at least three surfaces thereof are exposed.

8. The electrically conductive contact pin of claim 1, wherein the tip portion includes:
a first portion in contact with the plurality of metal layers constituting the body portion at the joint interfaces between the tip portion and the body portion; and
a second portion formed at the first portion, having a lower height than the first portion, and coming into contact with an object.

9. The electrically conductive contact pin of claim 1, wherein the tip portion includes:
a first portion in contact with the plurality of metal layers constituting the body portion at the joint interfaces between the tip portion and the body portion; and
a second portion formed at the first portion, having the same height as, but a narrower width than the first portion, and coming into contact with an object.

10. The electrically conductive contact pin of claim 1, wherein the tip portion includes:
a first portion in contact with the plurality of metal layers constituting the body portion at the joint interfaces between the tip portion and the body portion and at least partially embedded in the body portion; and
a second portion formed at the first portion and coming into contact with an object.

11. The electrically conductive contact pin of claim 1, wherein at each joint interface, the body portion is provided with a first engaging portion, and the tip portion is provided with a second engaging portion coupled to the first engaging portion to form a coupling reinforcement structure.

12. The electrically conductive contact pin of claim 11, wherein the first engaging portion is provided at the body portion along a height direction of the joint interface, and
the second engaging portion is provided at the tip portion along the height direction of the joint interface.

13. The electrically conductive contact pin of claim 11, wherein the first engaging portion is provided at the body portion along a perimeter direction of the joint interface, and
the second engaging portion is provided at the tip portion along the perimeter direction of the joint interface.
